(19) United States
(12) Patent Application Publication
(10) Pub. No.: US 2016/0043269 A1
(43) Pub. Date: Feb. 11, 2016

(54) METHOD FOR MANUFACTURING MULTI-JUNCTION STRUCTURE FOR PHOTOVOLTAIC CELL

(71) Applicant: COMMISSARIAT A L'ENERGIE ATOMIQUE ET AUX ENERGIES ALTERNATIVES, Paris (FR)

(72) Inventors: Emmanuelle LAGOUTTE, St Marcellin (FR); Thomas SIGNAMARCHEIX, Grenoble (FR)

(21) Appl. No.: 14/780,414

(22) PCT Filed: Mar. 24, 2014
(86) PCT No.: PCT/FR2014/050689

§ 371 Date: Sep. 25, 2015

(30) Foreign Application Priority Data
Mar. 25, 2013 (FR) 1352627

(51) Int. Cl. H01L 31/18; H01L 31/0687

(52) U.S. Cl. CPC H01L 31/1892; H01L 31/1804; H01L 31/184; H01L 31/0687

(57) ABSTRACT

Process for manufacturing a multi-junction structure for a photovoltaic cell. The process includes steps in: a) providing a first donor substrate including a first carrier substrate and a first seed layer including a first material; b) providing a second donor substrate including a second carrier substrate and a second layer including a second material different from the first material; c) bringing the first seed layer and the second layer into contact so as to obtain a direct bond between the first seed layer and the second layer with a view to forming the bonding interface; d) removing the first carrier substrate so as to expose the first seed layer; and e) epitaxially growing at least one first junction on the first seed layer.

The invention concerns a method for manufacturing a multi-junction structure for photovoltaic cell, the multi-junction structure comprising at least a first junction and at least a second junction connected together by a bonding interface. It concerns also a multi-junction structure for photovoltaic cell.

In order to enhance the cost-effectiveness of the use of solar cells, it is interesting to increase their conversion efficiency. In the field of the concentrating photovoltaic, the improvement of this efficiency is based on a clever stack of junctions allowing optimizing the absorption of the solar spectrum. To this end, it is necessary to manufacture solar cells called multi-junction solar cells comprising 4 to 6 junctions each allowing absorbing a range of wavelengths of the solar spectrum. To date, these solar cells may be carried out by manufacturing the junctions on top of each other by epitaxy of materials formed of alloys based, among others, on In, P, As and Ga. To collect the solar spectrum in a certain spectral range, the exact composition of alloys each forming junctions is extremely important. To each of these material compositions corresponds then a crystal lattice parameter of the junction. Indeed, the junction stack by epitaxial growth is based on a compromise between the composition of aimed junctions, and the accordance of the lattice parameter between each one of these junctions, which limits the possibilities for manufacturing stack of a large number of junctions from different materials. Thus, a junction <<a>> of composition cannot be necessarily carried out on a junction <<b>> if the lattice parameters of the different considered materials are too distanced and if a growth by very good quality homo-epitaxy cannot be ensured.

A promising variant of this manufacturing method consists of superimposing junctions produced separately by implementing the direct bonding technology also known under the name of bonding technology by molecular adhesion.

This technology has to meet two important criteria: the optical transparency of the assembly of junctions so that the solar radiation may cross the stack and be collected by each of the superimposed junctions, and the electrical conduction between the junctions so as to allow the collection of the generated current in each of junctions with a minimum of resistance, and thus, a minimum of losses.

Thus, the quality of the bonding interface between two junctions is critical to obtain an assembly by direct bonding which is of high quality. To this end, the topology of the surfaces to be assembled has to present in particular a very high planarity with high wavelength and a very low roughness with low wavelength. However, during the epitaxy of junctions, it is known that as the number of epitaxial layers increases, the defectivity at the surface increases in term of stresses (lattice parameters adaptation), epitaxies growth defects, roughness, etc. In the case of growth of junctions, over a dozen of layers with different compositions have to be carried out to obtain a final thickness in the order of the micrometer.

Therefore, the surface should be treated for its planarization for example by a mechano-chemical polishing step to decrease these defects and to achieve the requirements (roughness, flatness) of the direct bonding. This preparation step thus generates a substantial removal of material which cannot be carried out directly on the solar junction because the thickness of the various layers called junction layers is critical for its operation. A possible solution then consists of recovering this junction by a bonding layer of a material which does not affect the operation of the junction, which may be worked by a mechano-chemical polishing without fear of losing a very important quantity of material.

The presence of this bonding layer doesn't disturb the proper operation of the junctions, but it may however damage the operation of the stack of the junctions if it generates a pronounced optical absorption, blocking thus the transmission of photons in the lower junctions. The bonding layer so should have the thinnest thickness, which is extremely difficult to control during a thinning step by polishing in particular when we want to obtain a bonding layer thickness typically smaller than 100 nanometers presenting a very good uniformity over the entire substrate.

Moreover, in order to avoid a negative electrical impact, it is necessary that the layer ensuring the bonding has a low electrical resistivity. To this end, the implementation of the direct bonding technology is accompanied by a sealing thermal treatment to reduce the resistivity of the contact. In case of materials as InP and GaAs, thermal treatment temperatures in the order of 500° C. to 600° C. should be applied, which may generate a deterioration of the assembled junctions. Indeed, when junctions are obtained under thermal conditions of epitaxy in the order of 500° C. to 600° C., they do not tolerate or little such a high thermal budget.

One of the aims of the invention consists of overcoming at least one of these drawbacks.

To this end, the invention provides a method for manufacturing a multi-junction structure for a photovoltaic cell, the multi-junction structure comprising at least a first junction and at least a second junction connected together by a bonding interface, the method comprising the steps consisting of:

a) Supplying a first donor substrate comprising a first support substrate and a first seed layer including a first material

b) Supplying a second donor substrate comprising a second support substrate and a second seed layer including a second material different from the first material, the nature of the second material being different from that of the first material constituting the second support substrate,

c) Contacting the first seed layer and the second layer to obtain a direct bonding between the first seed layer and the second layer in order to constitute the bonding interface,

d) Removing the first support substrate so that to expose the first seed layer, and

e) Carrying out an epitaxy with at least the first junction on the first seed layer.

Thus, this method allows carrying out a junction subsequently to the direct bonding also known under the name of bonding by molecular adhesion, in order to be free from stresses related to the bonding. So it is possible to insert a step of sealing thermal treatment increasing the electrical conductivity of the bonding interface, before carrying out the epitaxy of the junction.

By difference of material nature, it is meant in the present application a material whose chemical composition is different. This excludes the differences obtained by doping. For example, a support substrate made of sapphire (Al2O3) has a material nature different from that of a second layer made of InP or GaAs.

In particular, respective surface topologies of the first seed layer and of the second layer are adapted to allow a direct bonding (or bonding by molecular adhesion) between the two surfaces. More particularly, in the present document, the surfaces intended to be put into contact for ensuring the direct bonding are planar and have for example a bow less than 50 μm for a 100 mm diameter substrate. They have furthermore a roughness typically less than 1 nanometer RMS.

According to one possibility, the first support substrate comprises a first detachment region allowing removing the first support substrate so that to expose the first seed layer.

According to one particular arrangement, the method comprises, prior to step a), a step j) consisting of implanting ionic species in the first donor substrate so as to form an embrittlement plane, forming the first detachment region and delimiting on both sides the first support substrate and the first seed layer, and the step d) of removing the first support substrate is carried out by detachment of the first support substrate at the embrittlement plane. The use of Smart Cut™ technology for removing the first support substrate thus makes it possible to obtain a first seed layer having a very thin uniform thickness (of a thickness up to 1 nanometer) generating a low optical absorption. Furthermore, the first seed layer obtained by this technique has a good planarity and a low roughness.

According to one variant, the method comprises, prior to step a), a step k) consisting of reporting, for example according to the Smart Cut™ technology, the first seed layer on the first support substrate by means of a layer forming the first detachment region comprising a buried detachment layer. Step d) of removing the first support substrate is furthermore carried out by laser irradiation performed at the absorption wavelength of the buried detachment layer.

In this variant, the support substrate is advantageously made of sapphire, the layer forming the first detachment region made of silicon oxide and the buried detachment layer made of silicon nitride so that the sapphire is transparent at the wavelength used during the laser irradiation

It is thus easy to obtain a first seed layer having a uniform thickness and being easy to control due to the fact that the etching of the first support substrate is no longer indispensable according to this method.

In parallel, the first support substrate removed in step d) is recycled for a reuse according to step j) or k) of the method.

Advantageously, the first seed layer comprises an etch-stop layer epitaxied on the surface of the first donor substrate and the method comprises, prior to step e), a step l) of thinning at least one part of the first seed layer until reaching respectively the etch-stop layer. Thus, it is possible to further thin the first seed layer in a controlled way. Step l) of thinning may be performed by any type of material removal, for example carried out by chemical, polishing or plasma etching. The etch-stop layer is particularly useful to limit the etching to at least one part of the first seed layer transferred by removing the first support substrate by Smart Cut™. It is thus possible to easily complete the thinning of the first seed layer if necessary or to remove the area which could be damaged by ionic implantation at the embrittlement plane. In this case, it is understood that the epitaxy takes place on the remaining first seed layer formed by the etch-stop layer.

The etch-stop layer may also allow completing the removal of the first support substrate by plasma, polishing and/or chemical etching, or by laser irradiation while allowing obtaining a thin and uniform layer thickness on the entire surface.

Furthermore, since the etch-stop layer is very thin, typically with a thickness less than 200 nm, it has the same surface topology than that on which it has been epitaxied, its presence does not generate an additional surface preparation step for the direct bonding.

According to one possibility, the method comprises, subsequently to step c), an application step of thermal treatment, preferably carried out at a temperature comprised between 200° C. and 800° C., and more preferably carried out at a temperature comprised between 300° C. and 600° C., for example with treatment periods comprised between few seconds and many hours, typically 3 hours. This thermal treatment allows reinforcing the direct bonding of the first layer with the second layer and decreasing the electrical resistivity of the bonding without deteriorating the first junction.

According to one possibility, the method comprises, subsequently to step e), a step o) comprising the manufacturing of the second junction when contacting the second layer.

According to one embodiment, the second donor substrate comprises at least a second junction inserted between the second support substrate and the second layer. Thus, the multi-junction structure is quickly obtained. This embodiment is in particular interesting when the second junction is carried out in a material which is little sensitive to the sealing thermal treatment of the direct bonding or when the reinforcing of the direct bonding does not require an application of a very important thermal budget and also when the second layer is optically highly transparent so that its thickness has little impact on the absorption of the solar spectrum of the multi-junction.

According to another embodiment, the method comprises, subsequently to step e) of epitaxy,
a step m) of bonding at least the first junction to a host substrate,
a step dd) of removing the second support substrate in order to expose the second layer, and
a step ee) of epitaxy of at least a second junction on said second layer.

It is thus possible to form at least a second junction after the direct bonding and the sealing thermal treatment.

According to one arrangement, the second support substrate comprises a second detachment region allowing the removal of the second support substrate in order to expose the second layer.

According to another arrangement, the second layer comprises an etch-stop layer epitaxied on the surface of the second donor substrate and prior to the step ee) of epitaxy of at least a second junction, the method comprises a thinning of at least part of the second layer until reaching the etch-stop layer. It is thus possible to thin in a simple and reproducible way the second layer so as to reduce the optical absorption of the layers in the bonding interface. The etch-stop layer may also complete the removal of the first support substrate by polishing, plasma and/or chemical etching, or by laser irradiation while allowing obtaining a thin and uniform layer thickness on the entire surface.

It is understood that the epitaxy in this case takes place on the remaining second layer formed by the etch-stop layer.

According to one possibility, the method comprises, prior to step b), a step jj) consisting of implanting ionic species in the second donor substrate to form an embrittlement plane, forming the second detachment region and delimiting on both sides the second support substrate and the second layer and the step dd) of removing the second support substrate comprises a detachment at the embrittlement plane delimiting the second layer and the second support substrate. It is thus possible to obtain a second layer which is thin, and may have the function of a seed layer for an epitaxy of at least one second junction. The etch stop layer may also complete the removal of the second support substrate after detachment by Smart Cut™ while allowing obtaining a thin and uniform layer thickness on the entire surface.

According to one variant, the method comprises, prior to step b), a step kk) consisting of bonding the second layer on a second support substrate for example made of sapphire by means of a layer, for example made of silicon oxide, forming the second detachment region, comprising a buried detachment layer, for example made of silicon nitride and the step dd) of removing the second support substrate comprises a laser irradiation step of the buried detachment layer of silicon nitride. Thus the second support substrate may be easily removed and recycled for a new use.

The etch stop layer may also complete the removal of the second support substrate after laser irradiation, such as after mechanical, plasma and/or chemical etching of the second support substrate, while allowing obtaining a thin and uniform layer thickness on the entire surface.

Preferably, the first seed layer and the second layer are each constituted by a monocrystalline semiconductor material selected from Ge and alloys based on at least one of the elements selected among In, P, As and Ga.

Thus, when these layers serve as seed for the epitaxy of at least one of the layers of a junction (they are then called seed layers), they are constituted by a material presenting a lattice parameter compatible with the growth by epitaxy of the desired material so as to from at least one of layers of the junction.

Preferably, the nature of the material of the first seed layer and of the second layer are selected so that their lattice parameter is close respectively to that of the at least one first junction and of the at least one second junction.

Advantageously, the lattice parameter of the first seed layer is close to that of the first junction in order to grow a very good quality monocrystalline material.

According to one possibility, the method comprises, prior to step a), a step i) of epitaxy of the first seed layer on the first support substrate and/or of the second layer on the second support substrate. When the first support substrate comprises on the surface a monocrystalline material whose lattice parameter is next to that of the first seed layer, the latter may then have a good quality (little dislocations, little rough surface) and be monocrystalline for the epitaxy of the first junction.

According to a second aspect, the invention provides a method for manufacturing a photovoltaic cell comprising a multi-junction structure manufactured as previously described.

According to a third aspect, the invention provides a method for manufacturing a photovoltaic system comprising a photovoltaic cell manufactured as previously described.

According to a fourth aspect, the invention provides a multi-junction structure comprising at least a first junction and at least a second junction connected by a bonding interface presenting a thickness less than 200 nanometers, an electrical resistivity lower than 50 mohm·cm² and a conversion efficiency greater than 40%.

Other aspects, aims and advantages of the present invention will clearly appear upon reading the following description of two embodiments thereof, given as non limiting examples and with reference to the annexed drawings. The figures do not necessarily respect the scale of all represented elements in order to improve their readability. Dotted lines illustrate an embrittlement plane formed by the implantation of ionic species. Continuous bold lines illustrate the direct bonding interface. In the rest of the description, for the purposes of simplification, identical, similar or equivalent elements of different embodiments have the same numeral references.

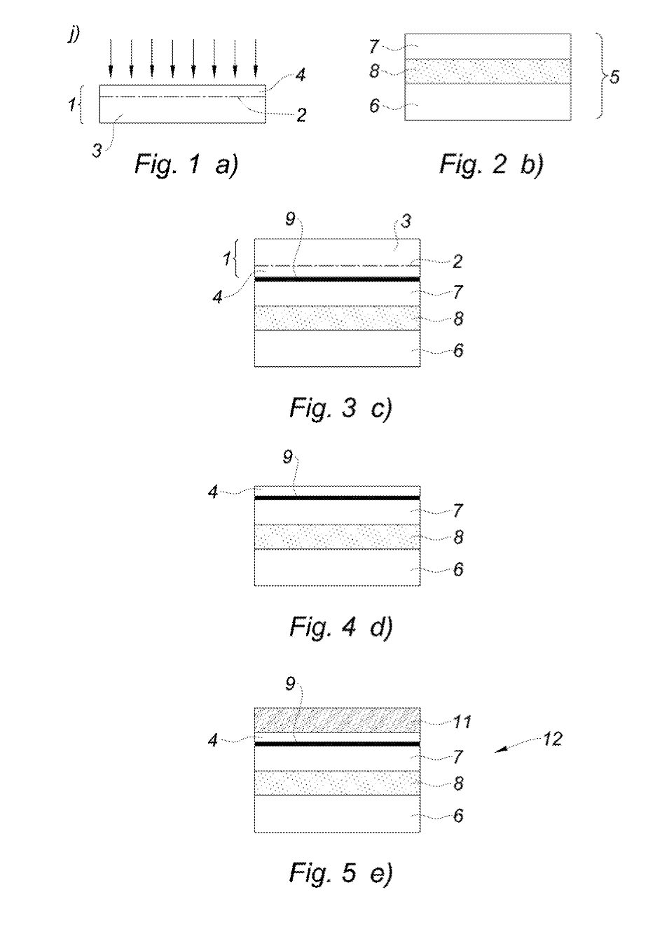

FIGS. 1 to 5 illustrate an embodiment of the method according to the invention.

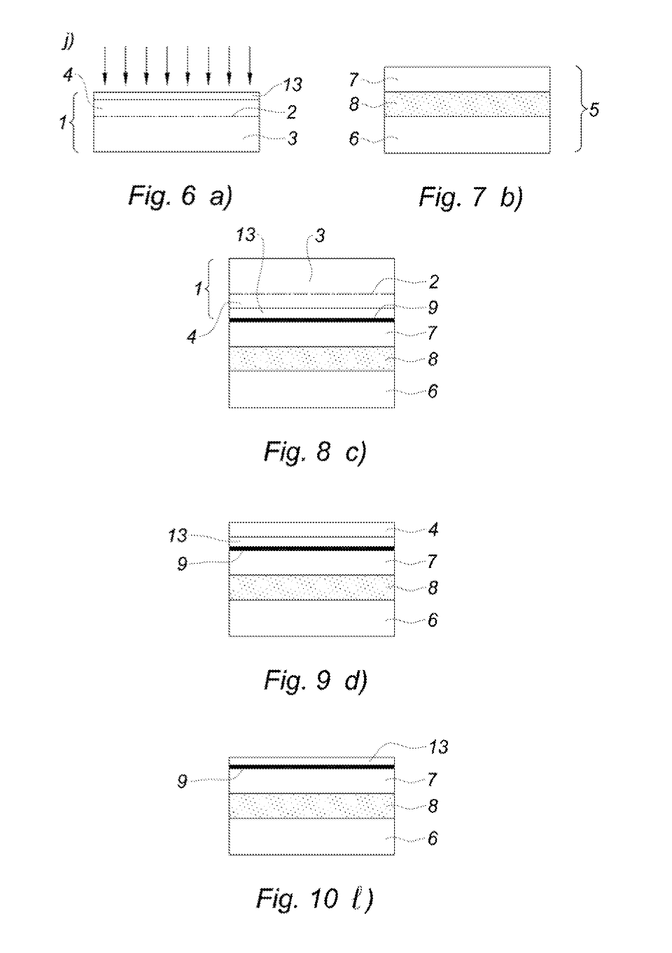

FIGS. 6 to 10 illustrate a variant of the previously illustrated embodiment.

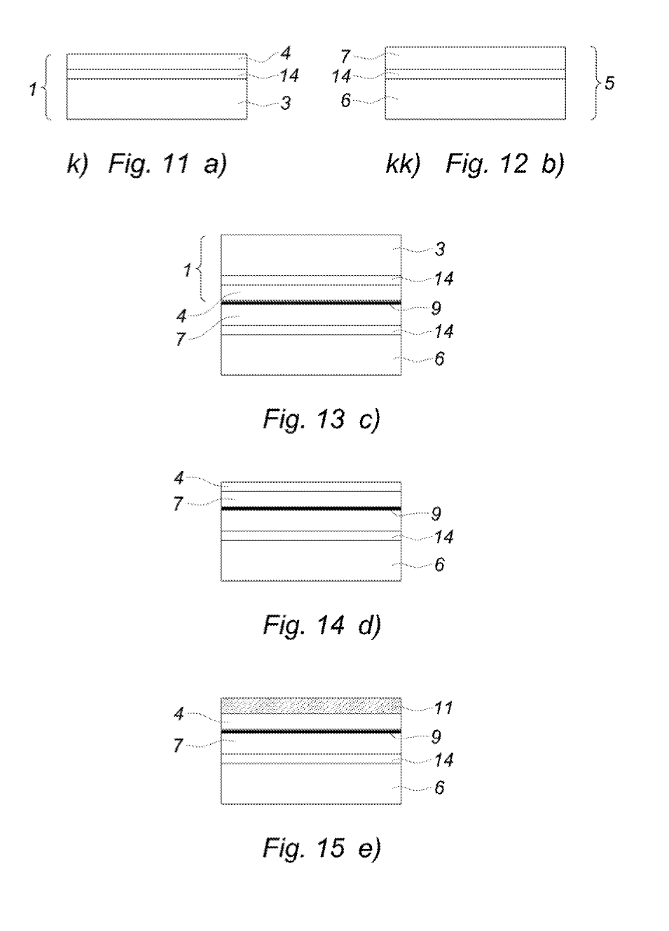

FIGS. 11 to 18 illustrate a second embodiment of the method according to the invention.

The FIG. 1 illustrates a step j) of the method consisting of implanting ionic species, for example with a dose comprised between 10^{E}16 and 10^{E}17 at/cm² of hydrogen-based ions, in a first donor substrate 1 of Ge, GaAs or InP, so as to form an embrittlement plane 2, forming the first detachment region and delimiting a first support substrate 3 and a first seed layer 4. The conditions of implementation allow creating an embrittlement plane 2 with a shallow depth of up to 1 nm in the first donor substrate 1 so that the seed layer 4 is very thin. At the end of this step j) is formed the first donor substrate 1 provided by a direct bonding according to step a) of the method.

FIG. 2 illustrates a step b) of the method consisting of providing a second donor substrate 5 comprising a second support substrate 6, a second layer 7 and a second junction 8 inserted between the second support substrate 6 and the second layer 7.

According to one possibility, the surfaces topologies of the first seed layer 4 and of the second layer 7 have been previously prepared so as to present a roughness less than 1 nanometer RMS and a planarity adapted to the direct bonding in the order of 50 μm for a substrate of 100 mm between both layers 4, 7.

FIG. 3 illustrates step c) of the method consisting of putting into contact the first seed layer 4 and the second layer 7 so as to constitute a bonding interface 9 and to obtain a direct bonding.

FIG. 4 illustrates the removal of the first support substrate 3 by detachment at the embrittlement plane 2. The first seed layer with a small thickness is thus exposed to carry out an epitaxy of a first junction 11 at its surface (FIG. 5). A multi-junction structure 12 is thus obtained by direct bonding comprising at least a first seed layer 4 serving also as small thickness bonding.

According to a non illustrated arrangement, a sealing thermal treatment of the direct bonding at 300° C. for a typical period ranging from few seconds to 120 min for example is applied to the structure before carrying out the epitaxy so as to reduce the electrical resistivity (typically less than 50 mohm·cm² of the contact obtained without deteriorating the second junction 8.

According to a non illustrated possibility, step d) of removing the first support substrate 3 is carried out by an application of a thermal treatment typically at a temperature of 100-350° C. and for a period comprised between 30 min and 120 min allowing at the same time the development of cavities at the embrittlement plane leading to the detachment of the first support substrate 3 and also the reinforcement of the sealing decreasing the electrical resistivity of the bonding.

According to one variant, step d) of removing the first support substrate 3 is obtained by application of a mechanical stress at the embrittlement plane 2 so as not to damage the second junction 8.

Moreover, a thermal treatment may be applied as a complement of the mechanical stress so as to obtain the detachment of the first support substrate 3, this thermal treatment participates then to the sealing promoting the decrease of the resistivity of the bonding interface 9.

FIGS. 6 to 10 illustrate a manufacturing method which is different from that illustrated in FIGS. 1 to 5 in that the first seed layer 4 comprises an etch-stop layer 13 on the surface of the first donor substrate 1 (FIG. 6). This etch-stop layer 13 is previously formed by epitaxy of a material presenting a reactivity which is different from the other part of the first seed layer 4 towards the (chemical, mechanical or plasma) etching. Once the direct bonding (FIG. 8) is performed with the second donor substrate 5 (FIG. 7), the first support substrate 3 is detached by application of a thermal treatment participating in the sealing of the bonding, completed by application of a mechanical stress laterally to the embrittlement plane 2 (FIG. 9). Then the first exposed seed layer 4 is thinned at least in part until reaching the etch-stop layer 13 (step l) FIG. 10). This etch-stop layer 13 obtained by epitaxy is monocrystalline and has a small uniform thickness and may be used as seed for the epitaxy of the first junction 11.

According to a non illustrated possibility, the first donor substrate 1 is a massive InP substrate comprising on the surface an etch-stop layer 13 made of InGaAs to the lattice parameter adapted for a subsequent growth of at least one junction. The ionic implantation based on hydrogen, helium or other gas species, forms an embrittlement plane 2 in the InP substrate 1 which delimits the first support substrate 3 made of InP and a first InP seed layer 4 comprising on the surface the InGaAs etch-stop layer 13. After the detachment of the first support substrate 3, at least part of the first seed layer 4 is removed for example by etching, polishing or plasma, until reaching the etch-stop layer 13. Then an epitaxy of a first junction 11 made of InGaAs is followed by the epitaxy of an additional InGaAsP junction so as to obtain a multi-junction structure 12.

FIGS. 12 to 18 illustrate a variant of the method according to the invention.

FIG. 11 illustrates a first donor substrate 1 comprising a first seed layer 4 made of GaAs bonded on the first support substrate 3 made of sapphire material (step k) by means of a silicon oxide layer 14 forming the first detachment region, comprising a silicon nitride layer (non illustrated). This previously bonding step may be carried out by Smart Cut™ technology allowing obtaining a first seed layer 4 with a controlled thickness of about 50 nanometers.

FIG. 12 illustrates a second donor substrate 5 comprising a second seed layer 7 made of InP with a thickness of about 50 nanometers bonded on a second support substrate 6, for example made of sapphire material, by means of bonding layers 14 (silicon oxide, silicon nitride, etc.) forming the second detachment region comprising at least a buried detachment layer of silicon nitride (non illustrated) (step kk).

FIG. 13 illustrates the putting into contact of the first seed layer 4 and of the second layer 7 whose surfaces have been previously prepared to obtain surface topologies adapted to the direct bonding (step c). Then a sealing thermal treatment of the direct bonding is applied at 600° C. for few seconds up to 2 hours allowing enhancing the electrical conductivity of the bonding interface 9 to less than 50 mohm·cm².

FIG. 14 illustrates step d) of removing the first support substrate 3 made of sapphire by laser irradiation through the latter at the absorption wavelength of the silicon nitride. This absorption generates the degradation of the silicon nitride layer, which allows the detachment of the support substrate 3. The latter may be advantageously recycled for a new use in a subsequent method.

FIG. 15 illustrates step e) consisting of carrying out an epitaxy of at least a first junction 11 made of AlGaAs or GaAs material on the first exposed seed layer 4 made of GaAs after cleaning the residues of the silicon oxide layer 14.

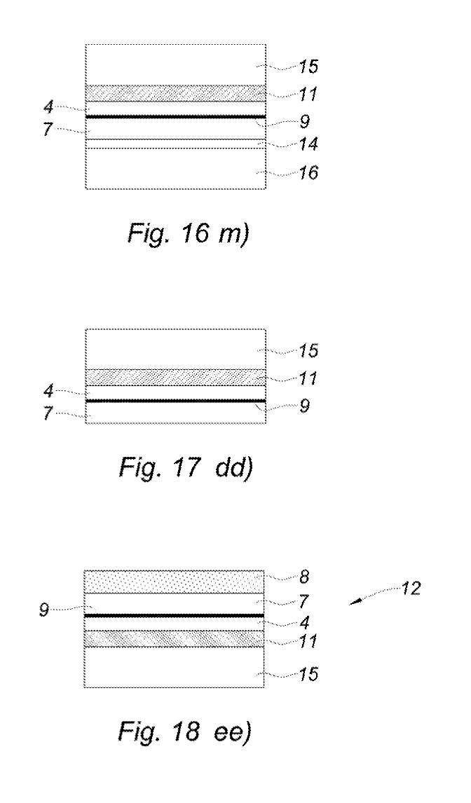

Then the first junction 11 is secured to a host substrate 15 such as for example a metal (Mo, Cu, etc.) or isolating (glass, sapphire, etc.) semiconductor substrate (Si, Ge, etc.) (FIG. 16—step m) so as to be able to perform the removal of the second support substrate 6 (step dd). This removal is performed in particular by laser irradiation such as previously described (FIG. 17).

Finally, the second InP layer 7 of the second donor substrate 5 being exposed, an epitaxy of at least one second junction 8 is carried out to obtain a multi-junction structure 12 presenting a thickness at the bonding interface 9 less than 200 nanometers and an electrical resistivity less than 50 mohm·cm² (step ee).

According to a non illustrated possibility, the second donor substrate 5 comprises two junctions 8, 8′ inserted between the second support substrate 6 and the second layer 7. Once the direct bonding carried out with the first seed layer 4 according to step c), step d) of the method comprises an epitaxy of two junctions 11, 11′, even an epitaxy of three junctions.

According to another non illustrated variant, the second donor substrate 5 comprising a second junction 8 is previously bonded with a second donor substrate 5 comprising another junction 8′. Subsequently to step c) of the method, three junctions 11, 11′ and 11″ are epitaxied on the first seed layer 4 according to step d) of the method.

The present invention allows thus considering all possible combinations of bonding of many junctions and of epitaxy of many junctions allowing obtaining multi-junction structures comprising 4, 5 even 6 junctions presenting weakly and optically absorbing bonding interfaces 9 and presenting a very good electrical conductivity.

Thus, the present invention provides the manufacturing of a multi-junction structure 12 comprising at least a first and at least a second junction 8, 11 connected by a bonding interface 9 simple to implement, preserving the integrity of the junction layers 8, 11 and which allows obtaining a weakly and optically absorbing bonding interface 9 and with a very good electrical conductivity.

It goes without saying that the invention is not limited to the variants described above as examples but that it comprises all technical equivalents and variants of the means described as well as their combinations.

1. A method for manufacturing a multi-junction structure for a photovoltaic cell, the multi-junction structure comprising at least a first junction and at least a second junction connected together by a bonding interface, the method comprising the steps of:
a) Supplying a first donor substrate comprising a first support substrate and a first seed layer including a first material,
b) Supplying a second donor substrate comprising a second support substrate and a second layer including a second material different from the first material, the nature of the second material being different from that of the first material constituting the second support substrate,
c) Putting into contact the first seed layer and the second layer so as to obtain a direct bonding between the first seed layer and the second layer in order to constitute the bonding interface,
d) Removing the first support substrate so as to expose the first seed layer, and
e) Carrying out an epitaxy of at least one first junction on the first seed layer.

2. The method according to claim 1, wherein the first seed layer comprises an etch-stop layer epitaxied on the surface respectively of the first donor substrate and in that the method comprises, prior to step e), a step I) of thinning at least part of the first seed layer until reaching respectively the etch-stop layer.

3. The method according to claim 1, wherein the first support substrate comprises a first detachment region allowing removing the first support substrate so as to expose the first seed layer.

4. The method according to claim 3, wherein the method comprises, prior to step a), a step j) of implanting ionic species in the first donor substrate so as to form an embrittlement plane forming the first detachment region and delimiting on both sides the first support substrate and the first seed layer and in that the step d) of removing the first support substrate is carried out by detachment of the first support substrate at the embrittlement plane.

5. The method according to claim 3, wherein the method comprises, prior to step a), a step k) of reporting the first seed layer on a first support substrate via a layer forming the first detachment region, comprising a buried detachment layer and in that step d) of removing the first support substrate is carried out by laser irradiation performed at the absorption wavelength of the buried detachment layer.

6. The method according to claim 1, wherein the method comprises, subsequently to step a), a step of application of a thermal treatment.

7. The method according to claim 1, wherein the second donor substrate comprises at least the second junction inserted between the second support substrate and the second layer.

8. The method according to claim 1, wherein the method comprises, subsequently to step e) of epitaxy,
a step m) of bonding of at least the first junction to a host substrate,
a step dd) of removal of the second support substrate so as to expose the second layer,
a step ee) of epitaxy of at least the second junction on said second layer.

9. The method according to claim 8, wherein the second layer comprises an etch-stop layer epitaxied on surface of the second donor substrate and in that before step ee) of epitaxy of at least the second junction, the method comprises a thinning of at least part of the second layer until reaching the etch-stop layer.

10. The method according to claim 8, wherein the second support substrate comprises a second detachment region allowing removing the second support substrate to expose the second layer.

11. The method according to claim 10, wherein the method comprises, prior to step b), a step jj) of implanting ionic species in the second donor substrate so as to form an embrittlement plane forming the second detachment region and delimiting on both sides the second support substrate and the second layer and in that step dd) of removing the second support substrate comprises a detachment at the embrittlement plane delimiting the second layer and the second support substrate.

12. The method according to claim 10, wherein the method comprises, prior to step b), a step kk) of bonding the second layer on a second support substrate via a layer forming the second detachment region, comprising at least a buried detachment layer and in that step dd) of removing the second support substrate comprises a laser irradiation step of the buried detachment layer.

13. The method according to claim 1, wherein the first seed layer and the second layer are each constituted by a monocrystalline semiconductor material selected from Ge and alloys based on at least one of the elements selected among In, P, As and Ga.

14. A method for manufacturing a photovoltaic cell wherein it comprises a multi-junction structure manufactured according to claim 1.

15. A method for manufacturing a photovoltaic system comprising a photovoltaic cell manufactured according to claim 14.
